(19) United States
(12) Patent Application Publication
(10) Pub. No.: US 2015/0129291 A1
(43) Pub. Date: May 14, 2015

(54) PRINTED CIRCUIT BOARD AND METHOD OF MANUFACTURING PRINTED CIRCUIT BOARD

(71) Applicant: SAMSUNG ELECTRO-MECHANICS CO., LTD., SUWON-SI (KR)

(72) Inventors: Sung Won JEONG, Suwon-Si (KR); Yong Yoon Cho, Suwon-Si (KR); Jung Hyun Park, Suwon-Si (KR); Ki Hwan Kim, Suwon-Si (KR); Da Hee Kim, Suwon-Si (KR); Gi Ho Han, Suwon-Si (KR)

(73) Assignee: SAMSUNG ELECTRO-MECHANICS CO., LTD., SUWON-SI (KR)

(21) Appl. No.: 14/540,028

(22) Filed: Nov. 12, 2014

(30) Foreign Application Priority Data
Nov. 14, 2013 (KR) 10-2013-0138562

(51) Int. Cl. H05K 1/02; C23F 1/02; H05K 3/38; H05K 1/09; H05K 3/00

(52) U.S. Cl. CPC H05K 1/0216; H05K 1/09; H05K 3/0041; H05K 3/388; H05K 3/384; C23F 1/02
USPC 174/257; 174/250; 216/13

(57) ABSTRACT

Disclosed herein is a printed circuit board, including: a substrate; a seed layer formed on the substrate; and a circuit pattern formed on the seed layer and formed so that a diameter of an upper portion thereof and a width of a lower portion thereof are equal to each other or a diameter of the lower portion is larger than that of the upper portion. Therefore, the printed circuit board according to a preferred embodiment of the present invention forms the circuit pattern having the lower portion having the diameter larger than that of the upper portion, such that the electrical signal loss may be decreased and separation of the circuit pattern may be prevented, thereby improving whole reliability of the board.

### CROSS REFERENCE TO RELATED APPLICATION

This application claims the benefit of Korean Patent Application No. 10-2013-0138562, filed on Nov. 14, 2013, entitled “Printed Circuit Board and Method of Manufacturing Printed Circuit Board”, which is hereby incorporated by reference in its entirety into this application.

### BACKGROUND OF THE INVENTION

1. Technical Field

The present invention relates to a printed circuit board and a method of manufacturing the printed circuit board.

2. Description of the Related Art

As a technology for satisfying highly densified trend and acceleration in a signal transmit speed of a semiconductor chip, a demand for a technology of directly mounting the semiconductor on a printed circuit board has been recently increased. Accordingly, a development for the printed circuit board having high density and high reliability capable of satisfying highly densified trend of the semiconductor has been demanded.

The requirements for the printed circuit board having high density and high reliability, which are closely associated with a specification of the semiconductor chip, involve many challenges such as fineness of a circuit, highly electrical characteristics, high speed signal transmit structure, high reliability, high functionality, and the like. In order to solve the challenges mentioned above, a printed circuit board technology capable of forming a micro-via has been required.

According to U.S. Pat. No. 6,240,636, a via hole may be generally processed by a laser or a drill. However, in the case in which the via hole is processed by the laser or the drill, a plurality of via holes need to be separately processed. In the case in which the via hole is processed by plasma, the plurality of via holes may be simultaneously processed. However, according to a plasma etching, the via hole is etched at a right angle due to straight property of the plasma. In the case in which the via hole is etched at a right angle rather than a tapered shape as described above, a foot of a resist may be caused. In addition, in the case in which a metal pattern is formed on the resist by a plating, a deposition, or the like, an undercut shape may be formed below the metal pattern due to a foot region of the resist. The metal pattern having the undercut shape may decrease adhesion with a board surface and increase specific resistance of the metal pattern, thereby causing signal loss of the circuit. Further, when the via hole is filled with an electroplating, voids may be formed in the via hole.

### SUMMARY OF THE INVENTION

Therefore, in the present invention, it was confirmed that an undercut region formed below circuit pattern is filled with a first plated layer on the circuit pattern and a second plated layer surrounding an upper portion and a side portion of the first plated layer, such that separation defect of the circuit layer may be prevented and a noise of an electrical signal may be decreased. The present invention has been completed based on the above-mentioned content.

The present invention has been made in an effort to provide a printed circuit board capable of decreasing electrical signal loss and preventing separation of a circuit pattern.

The present invention has been made in an effort to provide a method of manufacturing a printed circuit board capable of improving whole reliability of the board by forming a circuit pattern having the same formation areas of the upper and lower portions or an increased formation area of the lower portion.

According to a preferred embodiment of the present invention, there is provided a printed circuit board, including: a substrate; a seed layer formed on the substrate; and a circuit pattern formed on the seed layer and formed so that a diameter of an upper portion thereof and a width of a lower portion thereof are equal to each other or a diameter of the lower portion is larger than that of the upper portion, wherein the circuit pattern includes a first plated layer having an undercut region formed on the lower portion contacting the seed layer and a second plated layer surrounding an upper and side portions of the first plated layer and filling the undercut region.

The circuit pattern may be formed so that the diameter of the lower portion thereof is larger than that of the upper portion thereof.

The circuit pattern may be formed so that the diameter of the upper portion thereof and the diameter of the lower portion thereof are equal to each other.

The second plated layer may be formed on surfaces of the upper and side portions of the first plated layer at the same thickness.

The second plated layer may further include an expanded portion on a region contacting the seed layer.

The second plated layer and the expanded portion may be formed integrally with each other.

The seed layer may be made of any one conductive metal selected from copper, gold, nickel, platinum, palladium, and a mixture thereof.

The first plated layer may be made of any one of gold, silver, copper, and a combination thereof.

The second plated layer may be made of any one of nickel, gold, silver, and copper.

According to another preferred embodiment of the present invention, there is provided a method of manufacturing a printed circuit board, the method including: forming a seed layer on a substrate; forming a first resist layer on the seed layer; forming an opening part exposing the seed layer by etching the first resist layer, a foot region being formed on a region in which the seed layer and the first resist layer contact in the opening part; forming a first plated layer by filling the opening part, an undercut region being formed on a lower portion of the first plated layer; forming a second plated layer on the first plated layer, the second plated layer filling the undercut region; and forming a circuit pattern by etching the seed layer.

In the forming of the circuit pattern, a diameter of a lower portion of the circuit pattern may be formed to be larger than a diameter of an upper portion of the circuit pattern.

In the forming of the circuit pattern, a diameter of an upper portion of the circuit pattern and a diameter of a lower portion of the circuit pattern may be formed to be equal to each other.

In the forming of the first plated layer, the undercut region of the second plated layer may be formed to correspond to the foot region formed on the first plated layer.

The method may further include, before the forming of the second plated layer, removing the first resist layer; forming a second resist layer on the substrate; and exposing the first plated layer by patterning the second resist layer.

The first resist layer and the second resist layer may be formed by a photo resist or a dry film resist.

In the forming of the second plated layer, the second plated layer may be formed by an anisotropic plating method.

In the forming of the second plated layer, an expanded portion formed by expanding the second plated layer may be further formed on the undercut region.

The method may further include, before the forming of the circuit pattern, forming a third resist layer on an entire surface of the substrate; covering the second plated layer by patterning the third resist layer; and exposing the seed layer.

In the forming of the opening part, the opening part may be formed by exposing the first resist layer to ultraviolet light and developing the exposed first resist layer.

In the forming of the circuit pattern, the circuit pattern may be formed by the first plated layer formed so that a diameter of an upper portion thereof is larger than a diameter of a lower portion thereof, and the second plated layer surrounding upper and side portions of the first plated layer and formed so that a diameter of a lower portion of the circuit pattern is larger than that of an upper portion thereof.

### BRIEF DESCRIPTION OF THE DRAWINGS

The above and other objects, features and advantages of the present invention will be more clearly understood from the following detailed description taken in conjunction with the accompanying drawings, in which:

FIG. 1 is a cross-sectional view showing a printed circuit board according to a preferred embodiment of the present invention; and

FIGS. 2 to 10 are views showing a method of manufacturing a printed circuit board according to a preferred embodiment of the present invention.

### DESCRIPTION OF THE PREFERRED EMBODIMENTS

The objects, features and advantages of the present invention will be more clearly understood from the following detailed description of the preferred embodiments taken in conjunction with the accompanying drawings. Throughout the accompanying drawings, the same reference numerals are used to designate the same or similar components, and redundant descriptions thereof are omitted. Further, in the following description, the terms “first”, “second”, one side“, the other side” and the like are used to differentiate a certain component from other components, but the configuration of such components should not be construed to be limited by the terms. Further, in the description of the present invention, when it is determined that the detailed description of the related art would obscure the gist of the present invention, the description thereof will be omitted.

Hereinafter, a preferred embodiment of the present invention will be described in detail with reference to the accompanying drawings.

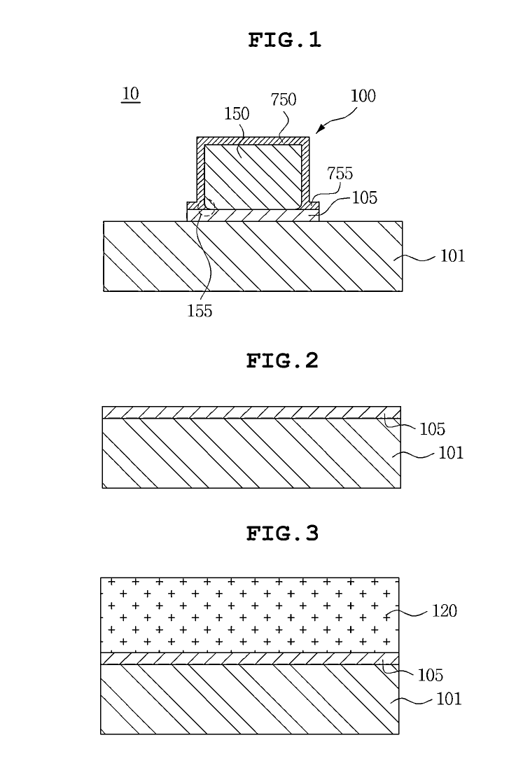

FIG. 1 is a cross-sectional view showing a printed circuit board according to a preferred embodiment of the present invention.

Referring to FIG. 1, a printed circuit board 10 may include a substrate 101, a seed layer 105 formed on the substrate 101, and a circuit pattern 100 formed on the seed layer 105 and formed so that diameters of upper and lower portions are equal to each other or a diameter of the lower portion is larger than that of the upper portion.

Here, the circuit pattern 100 may include a first plated layer 150 having an undercut region 155 formed on a lower portion of the first plated layer 150 contacting the seed layer 105, and a second plated layer 750 formed on surfaces of an upper portion and a side portion of the first plated layer 150 at the same thickness, filling the undercut region 155, and plated so that diameters of upper and lower portions of the circuit pattern 100 are equal to each other or the diameter of the lower portion of the circuit pattern 100 is larger than that of the upper portion thereof.

The substrate 101 may be generally made of a complex polymer resin used as an interlayer insulating material. For example, a prepreg is employed as the substrate 101, thereby making it possible to manufacture the printed circuit board 10 to be thinner. Alternatively, an ajinomoto build up film (ABF) is employed as the substrate 101, thereby making it possible to easily implement a fine circuit. In addition to this, the substrate 101 may use an epoxy based resin such as FR-4, bismaleimide triazine (BT), or the like, but is not particularly limited thereto. Alternatively, the substrate 101 may also use a copper clad laminate (CCL). According to a preferred embodiment of the present invention, the substrate 101 may use the copper clad laminate or the polymer resin.

The seed layer 105 may be formed to serve as a lead line for performing an electroplating on the substrate 101 which is made of the polymer resin. The seed layer 105 may be formed by a wet plating method such as an electroless plating method. In addition, the seed layer 105 may be formed by a dry plating method such as a sputtering. The seed layer 105 may be made of any one conductive metal selected from copper, gold, nickel, platinum, palladium, and a mixture thereof.

The circuit pattern 100 may be formed on the seed layer 105. The circuit pattern 100 may be formed so that the diameter of the upper portion of the circuit pattern 100 and the diameter of the lower portion thereof, that is, a surface contacting a surface of the seed layer 105 are equal to each other or the diameter of the lower portion of the circuit pattern 100 is larger than that of the upper portion of the circuit pattern 100.

As such, by forming a formation area of the lower portion of the circuit pattern 100 to be larger, separation of the circuit pattern 100 may be prevented and reliability of the circuit pattern 100 as a wiring may be improved. In addition, by forming the formation area of the upper and lower portions of the circuit pattern 100 to be equal to each other, separation of the circuit pattern 100 may be prevented and electrical signal loss may be prevented.

Meanwhile, the circuit pattern 100 may include the first plated layer 150 and the second plated layer surrounding an outer portion of the first plated layer 150.

The first plated layer 150 is formed so that a diameter of a lower portion contacting the seed layer 105 is smaller than a diameter of an upper portion. As a result, since an underlayer of a resist used when forming the first plated layer 150 has low hardness, a foot region may be formed, such that the undercut region 155 may be formed on the lower portion of the first plated layer 150. Thereby, the diameter of the lower portion of the first plated layer 150 may be formed to be smaller than the diameter of the upper portion thereof. A detailed description thereof will be provided in a description of a manufacturing process described below.

When the first plated layer 150 having the undercut region 155 formed as described above is used as the circuit pattern 100, a phenomenon in which the first plated layer 150 is separated from the seed layer 105 may be caused. In addition, the electrical signal loss may be caused by different diameters of the upper and lower portions as in the first plated layer 150.

The second plated layer 750 surrounding the outer portion of the first plated layer 150 may be formed on the first plated layer 150. The second plated layer 750 may be plated on the upper and side portions of the first plated layer 150 at the same thickness.

In addition, the second conductive layer 750 fills the undercut region 155 formed in the first conductive layer 150. Here, in the case in which the second plated layer 750 is formed at the same thickness, as in the upper and side portions thereof, since the second plated layer 750 is formed in a shape such as the undercut region 155, a material of the second plated layer 750 may be filled in the undercut region 155 by an anisotropic plating.

In addition, by the second plated layer 750, the diameters of the upper portion and the lower portion of the circuit pattern 100 may be formed to be equal to each other and the diameter of the lower portion of the circuit pattern 100 may be formed to be larger than that of the upper portion thereof. Here, a region in which the second plated layer 750 is formed to be larger refers to as an expanded portion 755. The expanded portion 755 may be formed so as to contact the seed layer 105 and may be formed integrally with the plated layer 750.

Therefore, since adhesion between the seed layer 105 and the second plated layer 750 is improved by forming the expanded portion 755 in the second plated layer 750, adhesion of the first plated layer 150 surrounded by the second plated layer 750 may be improved. Further, problems such as separation defect and like of the first plated layer 150 and the circuit pattern 100 may be solved and reliability of the entire printed circuit board 10 may be improved. In addition, the second plated layer 750 may be plated on the first plated layer 150 and may be made of copper, gold, silver, and a combination thereof having electrical conductivity.

As such the circuit pattern 100 is formed by a first plated layer 150 formed so that the diameter of the upper portion is larger than the diameter of the lower portion and the second plated layer 750 surrounding the upper and side portions of the first plated layer 150 and formed so that the diameters of the upper and lower portions of the circuit pattern 100 are equal to each other or the diameter of the lower portion of the circuit pattern 100 is larger than that of the upper portion thereof.

Therefore, by further forming the second plated layer 750 filling the undercut region 155 on the first plated layer 150 having the undercut region 155, the problems such as separation defect of the circuit pattern 100 and like may be solved and reliability of the entire printed circuit board 10 may be improved.

FIGS. 2 to 10 are views showing a method of manufacturing a printed circuit board according to a preferred embodiment of the present invention. Here, for convenience of explanation and in order to avoid an overlapped description, a description will be made with reference to FIG. 1.

As shown in FIG. 2, the seed layer is formed on the substrate. The substrate 101 may be generally made of a complex polymer resin used as an insulating material. For example, the substrate 101 may be made of a prepreg, ajinomoto build up Film (ABF), or an epoxy based resin such as FR-4, a bismaleimide triazine (BT) or the like. In addition, the substrate 101 may be formed in a film form. However, the preferred embodiment of the present invention does not limit the material and form of the substrate.

The seed layer 105 may be made of a conductive metal. For example, the conductive metal may be any one electrically conductible metal selected from copper, gold, nickel, platinum, palladium, and a mixture thereof. Although the drawings shown show a case in which the seed layer 105 is formed by a single layer, the seed layer may be formed by a plurality of layers in some cases.

As shown in FIG. 3, a first resist layer 120 is formed on the seed layer 105. The first resist layer 120 may be formed to have a thickness of a range of 10 μm to 150 μm. In addition, the first resist layer may be formed by a spin coating method, or the like.

The first resist layer 120 may be formed by a photo resist (PR) or a dry film resist (DFR). Since the dry film resist and the photo resist are photosensitive, they may be used for forming a pattern by curing the resist with an exposure method. Here, the photo resist may use any one of positive or negative.

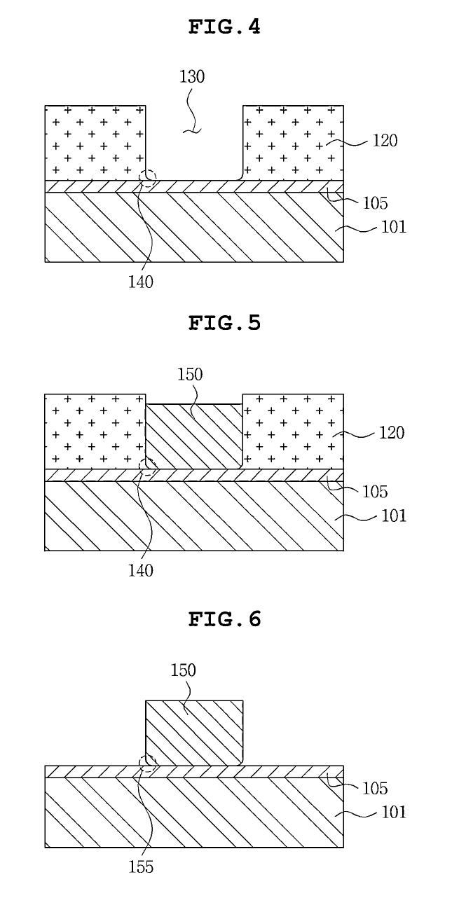

As shown in FIG. 4, an opening part 130 may be formed by etching the first resist layer 120. Here, when a photosensitive resistive is used as the first resist layer 120, the opening part may be formed by the exposure method, and when a resist other than the photosensitive resist is used, the opening part 130 may be formed by ashing the first resist layer 120 with plasma using an etcher.

A foot region 140 may be formed on a lower portion of the opening part 130 formed by the ashing or the exposure method as described above. The foot region 140 may form the opening part 130 by curing and developing the photosensitive resist by using ultraviolet light when using the photosensitive resist. In this case, sufficient exposure energy is not transferred to the lower portion of the photosensitive resist due to an exposure amount or a thickness of the photosensitive resist, such that an uncured or cured (collectively referred to as “unreacted”) region may be formed. The unreacted region remains in processes such as the exposing process, the developing process, and the like. As such, a portion remaining as the unreacted region may be formed as the foot region 140.

Alternatively, an etching method using the plasma may etch the opening part 130 at a right angle due to straight property of the plasma. However, since sufficient plasma energy is not transferred to the resist layer, the ashing may not be sufficiently performed. Therefore, the remaining unreacted region may be formed and the region remaining as the unreacted region may be formed on a contacting portion between the resist and seed layer 105, that is, an edge portion of the opening part, thereby forming the foot region 140.

As shown in FIG. 5, the first plated layer 150 is formed by filling the opening part 130. The seed layer 105 is exposed on the lower portion of the opening part 130. Here, when a plating process is performed on the seed layer 105, the opening part 130 is filled, thereby making it possible to form the first plated layer 150. Here, the first plated layer 150 may be made of any one of gold, silver, copper, and a combination thereof.

As shown in FIG. 6, a first resist layer 120 of the substrate having the first plated layer 150 formed thereon is removed. The undercut region 155 may be formed on the lower portion of the first plated layer 150 remaining after removing the first resist layer 120.

As such, the upper and lower portion of the first plated layer 150 may be formed to have the diameter different from each other due to the undercut region 155. In other words, the upper and lower portion of the first plated layer 150 may be formed to have the diameter different from each other due to the foot region 140 formed in the first resist layer 120. Although the diameter of the upper portion through the side portion of the first plated layer 150 may be formed to be equal, a region adjacent to the seed layer 105 may be formed to have a diameter different from the diameter of the upper portion due to the undercut region 155.

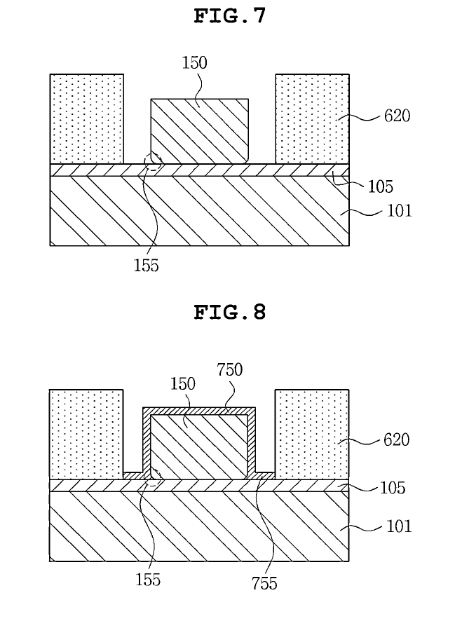

As shown in FIG. 7, a second resist layer 620 is formed on the substrate having the first plated layer 150 formed thereon and is then etched, thereby making it possible to expose the first plated layer 150. In this case, the second resist layer 620 is etched so that the side portion of the first plated layer 150 is exposed. The side portion of the first plated layer 150 needs to be exposed so that the undercut region 155 is plated during a plating process which is subsequently performed. Here, the second resist layer 620 may be formed by the photosensitive resist or the dry film resist.

As shown in FIG. 8, the second plated layer 750 is formed by plating the substrate on which the first plated layer 150 is exposed. The second plated layer 750 may be plated on the first plated layer 150 and may be made of copper, gold, silver, and a combination thereof having electrical conductivity.

The second plated layer 750 may be formed by an anisotropic plating method. In order to fill the undercut region 155 formed in the first plated layer 150, the anisotropic plating method may be performed. As shown in FIG. 8, in order to allow the second resist layer 620 to expose the side portion of the first plated layer 150, an opening part is formed between the side portion of the first plated layer 150 and an exposed side portion of the second resist layer 620. The undercut region 155 may be anisotropically plated by adjusting a concentration of a plating solution in the opening part. Further, the plating may be performed on the exposed seed layer 105 for forming the opening part. Therefore, an expanded portion 755 extended from the second plated layer 750 may be formed on the lower portion of the second plated layer 750. Therefore, by forming the expanded portion 755, an electrical signal transfer function may be improved and separation defect may be prevented.

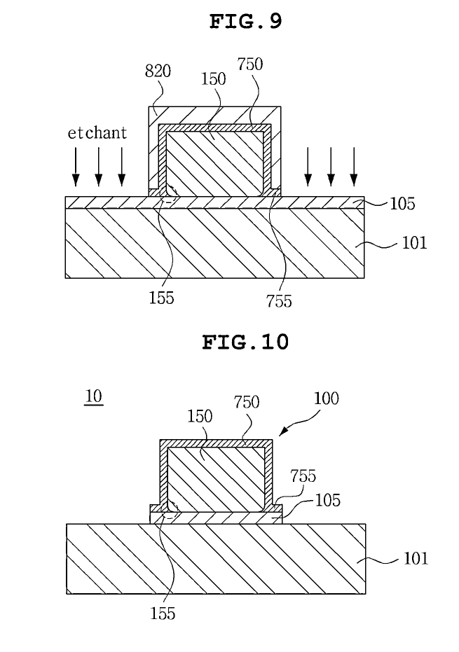

As shown in FIG. 9, the second resist layer 620 remaining on the substrate having the second plated layer 750 formed thereon is removed and a third resist layer 820 is again formed. In addition, the third resist layer 820 is patterned to cover the region in which the first plated layer 150 and the second plated layer 750 are formed and other regions are removed to expose the seed layer 105. Here, a portion of the expanded portion 755 may also be exposed while the seed layer 105 is exposed. In addition, the exposed seed layer 105 may be etched by using an etchant. As the etchant, a known etchant may be used.

As such, a surface of the substrate may be exposed by etching the seed layer 105. In this case, a portion of the expanded portion 755 may be etched while the seed layer 105 is etched. Here, an etching shape of the expanded portion 755 may be formed to have the same thickness as the side portion of the second plated layer 750 by adjusting an etching amount. In addition, a portion of the expanded portion 755 is left, such that the diameter of the lower portion of the second plated layer 750 may be formed to be larger than the diameter of the upper portion of the second plated layer 750.

As shown in FIG. 10, the seed layer 105 is etched and the third resist layer 820 covering the circuit pattern 100 is removed, thereby making it possible to form the circuit pattern 100.

Here, the circuit pattern 100 may include the first plated layer 150 having the undercut region 155 formed on the lower portion of the first plated layer 150 contacting the seed layer 105, and the second plated layer 750 formed on the surfaces of the upper portion and the side portion of the first plated layer 150 at the same thickness, filling the undercut region 155, and plated so that the diameters of the upper and lower portions of the circuit pattern 100 are equal to each other or the diameter of the lower portion of the circuit pattern 100 is larger than that of the upper portion thereof.

The circuit pattern 100 may be formed by the first plated layer 150 having the upper portion having the diameter larger than the lower portion and the second plated layer 750 surrounding the upper and side portions of the first plated layer 150 and formed so that the diameters of the upper and lower portions of the circuit pattern 100 are equal to each other or the diameter of the lower portion of the circuit pattern 100 is larger than that of the upper portion thereof.

The printed circuit board and the method of manufacturing the printed circuit board according to the preferred embodiments of the present invention form the circuit pattern having the lower portion having the diameter larger than that of the upper portion, such that the electrical signal loss may be decreased and separation of the circuit pattern may be prevented, thereby improving whole reliability of the board.

Although the embodiments of the present invention have been disclosed for illustrative purposes, it will be appreciated that the present invention is not limited thereto, and those skilled in the art will appreciate that various modifications, additions and substitutions are possible, without departing from the scope and spirit of the invention.

Accordingly, any and all modifications, variations or equivalent arrangements should be considered to be within the scope of the invention, and the detailed scope of the invention will be disclosed by the accompanying claims.

What is claimed is:

1. A printed circuit board, comprising:
a substrate;
a seed layer formed on the substrate; and
a circuit pattern formed on the seed layer and formed so that a diameter of an upper portion thereof and a width of a lower portion thereof are equal to each other or a diameter of the lower portion is larger than that of the upper portion,
wherein the circuit pattern includes a first plated layer having an undercut region formed on the lower portion contacting the seed layer and a second plated layer surrounding an upper and side portions of the first plated layer and filling the undercut region.

2. The printed circuit board as set forth in claim 1, wherein the circuit pattern is formed so that the diameter of the lower portion thereof is larger than that of the upper portion thereof.

3. The printed circuit board as set forth in claim 1, wherein the circuit pattern is formed so that the diameter of the upper portion thereof and the diameter of the lower portion thereof are equal to each other.

4. The printed circuit board as set forth in claim 1, wherein the second plated layer is formed on surfaces of the upper and side portions of the first plated layer at the same thickness.

5. The printed circuit board as set forth in claim 1, wherein the second plated layer further includes an expanded portion on a region contacting the seed layer.

6. The printed circuit board as set forth in claim 5, wherein the second plated layer and the expanded portion are formed integrally with each other.

7. The printed circuit board as set forth in claim 1, wherein the seed layer is made of any one conductive metal selected from copper, gold, nickel, platinum, palladium, and a mixture thereof.

8. The printed circuit board as set forth in claim 1, wherein the first plated layer is made of any one of gold, silver, copper, and a combination thereof.

9. The printed circuit board as set forth in claim 1, wherein the second plated layer is made of any one of nickel, gold, silver, and copper.

10. A method of manufacturing a printed circuit board, the method comprising:
forming a seed layer on a substrate;
forming a first resist layer on the seed layer;
forming an opening part exposing the seed layer by etching the first resist layer, a foot region being formed on a region in which the seed layer and the first resist layer contact in the opening part;
forming a first plated layer by filling the opening part, an undercut region being formed on a lower portion of the first plated layer;
forming a second plated layer on the first plated layer, the second plated layer filling the undercut region; and
forming a circuit pattern by etching the seed layer.

11. The method as set forth in claim 10, wherein in the forming of the circuit pattern, a diameter of a lower portion of the circuit pattern is formed to be larger than a diameter of an upper portion of the circuit pattern.

12. The method as set forth in claim 10, wherein in the forming of the circuit pattern, a diameter of an upper portion of the circuit pattern and a diameter of a lower portion of the circuit pattern are formed to be equal to each other.

13. The method as set forth in claim 10, wherein in the forming of the first plated layer, the undercut region of the second plated layer is formed to correspond to the foot region formed on the first plated layer.

14. The method as set forth in claim 10, further comprising, before the forming of the second plated layer,
removing the first resist layer;
forming a second resist layer on the substrate; and
exposing the first plated layer by patterning the second resist layer.

15. The method as set forth in claim 14, wherein the first resist layer and the second resist layer are formed by a photo resist or a dry film resist.

16. The method as set forth in claim 10, wherein in the forming of the second plated layer, the second plated layer is formed by an anisotropic plating method.

17. The method as set forth in claim 10, wherein in the forming of the second plated layer, an expanded portion formed by expanding the second plated layer is further formed on the undercut region.

18. The method as set forth in claim 10, further comprising, before the forming of the circuit pattern,
forming a third resist layer on an entire surface of the substrate;
covering the second plated layer by patterning the third resist layer; and
exposing the seed layer.

19. The method as set forth in claim 10, wherein in the forming of the opening part, the opening part is formed by exposing the first resist layer to ultraviolet light and developing the exposed first resist layer.

20. The method as set forth in claim 10, wherein in the forming of the circuit pattern, the circuit pattern is formed by the first plated layer formed so that a diameter of an upper portion thereof is larger than a diameter of a lower portion thereof and the second plated layer surrounding upper and side portions of the first plated layer and formed so that a diameter of a lower portion of the circuit pattern is larger than that of an upper portion thereof.
